(19) United States
(12) Patent Application Publication
(10) Pub. No.: US 2020/0326387 A1
(43) Pub. Date: Oct. 15, 2020

(54) AUTOMATIC TEST SYSTEM OF WIRELESS CHARGING SYSTEM

(71) Applicant: SICHUAN ENERGY INTERNET RESEARCH INSTITUTE, TSINGHUA UNIVERSITY, Chengdu, Sichuan (CN)

(72) Inventors: Tun LI, Chengdu, Sichuan (CN); Siming PAN, Chengdu, Sichuan (CN); Dawei HE, Chengdu, Sichuan (CN); Yi LIU, Chengdu, Sichuan (CN); Jingdong SUN, Chengdu, Sichuan (CN)

(21) Appl. No.: 16/772,701

(22) PCT Filed: Apr. 19, 2018
(86) PCT No.: PCT/CN2018/083639

§ 371 Date: Jun. 12, 2020

(30) Foreign Application Priority Data
Dec. 13, 2017 (CN) 201711324093.3

(51) Int. Cl. G01R 33/02; G01R 31/40; B25J 19/00; H02J 7/02; H02J 50/10; H02J 7/00

(52) U.S. Cl. CPC G01R 33/02; G01R 31/40; B25J 19/0029; B25J 9/0096; H02J 50/10; H02J 7/0047; H02J 7/02

(57) ABSTRACT

The present invention discloses an automatic test system for testing a wireless charging system. The automatic test system may comprise a robot arm, a test plane, a docking station and a control computer. The robot arm is configured to grip a first fixture. The test plane is configured to grip a second fixture. The docking station is connected to the robot arm. The control computer is configured to control the robot arm and receive test data. The second fixture is configured to grip a device under test of the wireless charging system, and the first fixture is configured to grip a test device for testing the device under test and generate test data.

### FIELD OF THE INVENTION

The present invention relates to the field of wireless charging systems, and more particularly to an automatic test system for testing and characterizing a wireless charging system.

### DESCRIPTION OF THE RELATED ART

Wireless charging is an evolving technology that brings new convenience to charging electronic devices. In wireless charging systems, particularly inductive wireless charging systems, energy is transferred from one or more power transmitter (TX) coils to one or more power receiver (RX) coils by means of magnetic field coupling.

The magnetic coil may generate a magnetic field, and the magnetic coupling between the TX and RX coils may affect the charging efficiency of the wireless charging system. In order to improve the user experience and ensure the reliability of wireless charging, the wireless charging system should be fully tested and verified. Test systems commonly used to characterize wireless charging systems often involve a large amount of manual interaction, such as manual adjustment of test settings. Artificial interactions may introduce experimental errors and affect the reliability of test results. In addition, testing of wireless charging systems may comprise different wireless charging system test conditions and scenarios at different stages, while currently available test systems do not meet all of the different test requirements and support all different test scenarios.

The present application proposes an automatic test system for testing a wireless charging system. The automatic test system is capable of evaluating multiple parameters of a wireless charging system at all stages of development. In addition, such system may be manually and automatically controlled by a software program to ensure the reliability and consistency of test results.

### SUMMARY OF THE INVENTION

One aspect of the present invention relates to an automatic test system for testing a wireless charging system. The automatic test system may comprise a robot arm, a test plane, a docking station and a control computer. The robot arm is configured to grip a first fixture. The test plane is configured to grip a second fixture. The docking station is connected to the robot arm. The control computer is configured to control the robot arm and receive test data. The second fixture is configured to control a device under test of the wireless charging system, and the first fixture is configured to control a test device for testing the device under test and to generate test data.

Another aspect of the present invention relates to an automatic test system for testing a wireless charging system. The system may comprise a robot arm configured to control a test plane of a device under test of the wireless charging system, a docking station connected to a robot arm, and a control computer configured to control the robot arm and receive test data. The robot arm may comprise a distal portion that is configured to be releasably connected to a plurality of types of devices selected from a fixture, a probe and a test device. The control computer may comprise a non-transitory computer readable medium storing program codes for controlling a testing process, and measuring and analyzing the test data.

Another aspect of the present invention relates to an automatic test system for testing a wireless charging system. The system may comprise a robot arm configured to control a first fixture, a test plane configured to grip a second fixture, a docking station connected to a robot arm, and a control computer configured to control the robot arm and receive test data. The first and second fixtures may comprise connector s that are configured to electrically connect to a device for testing. The robot arm may comprise an internal data line through which the device connected by the first fixture communicates with the control computer.

It should to be understood that both that general description and the following detail description are exemplary and explanatory only and are not restrictive of the present invention, as claimed.

### BRIEF DESCRIPTION OF THE DRAWINGS

The drawings that form a part of the present invention illustrate several non-limiting embodiments and, together with the description, are configured to explain the disclosed principles.

FIG. 1 is a schematic diagram of an automatic test system according to an exemplary embodiment of the present invention;

FIG. 2 is a schematic diagram of an automatic test system equipped with a fixture mounted according to an exemplary embodiment of the present invention;

FIG. 3 is a schematic diagram of an automatic test system for measuring a magnetic field generated by a magnetic coil according to an exemplary embodiment of the present invention;

FIG. 4 is a schematic diagram of an automatic test system for measuring the efficiency and charging area of a wireless charging system according to an exemplary embodiment of the present invention; and

FIG. 5 is a schematic diagram of an automatic test system for measuring the coupling coefficient of a wireless charging system according to an exemplary embodiment of the present invention.

### DESCRIPTION OF THE PREFERRED EMBODIMENTS

Reference will now be made in detail to the exemplary embodiments. The description below refers to the accompanying drawings. Unless otherwise indicated, the same marks in different figure represent the same or similar elements. The embodiments set forth in the following description of exemplary embodiments according to the present invention are not intended to represent all implementations according to the present invention. Instead, they are merely examples of systems and methods consistent with aspects of the present invention.

The development of wireless charging systems may go through multiple phases, and at each phase, testing and characterization of wireless charging systems may require different conditions and scenarios. For example, in the early phase of coil design, it may be necessary to evaluate the uniformity of the magnetic field generated by the magnetic coils of the wireless charging system. During the prototype verification phase, it may be necessary to estimate the efficiency and threshold voltage (e.g., rectifier voltage) of the wireless charging system. In the later product phase, it may be necessary to test the charging area and temperature of the wireless charging system. In addition, during the product certification phase, the radiation from the wireless charging system may need to be tested and limited. The present invention proposes an automatic test system for testing and characterizing a wireless charging system. The automatic test system may be used to test a wireless charging system at various stages and to meet a variety of test conditions and scenarios.

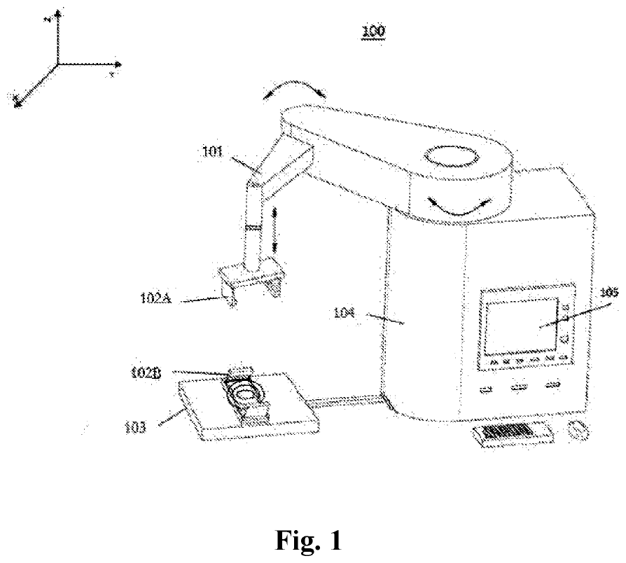

FIG. 1 illustrates an automatic test system 100 according to an exemplary embodiment of the present invention. The system 100 may comprise multiple components, some of which may be optional. In some embodiments, the system 100 may comprise more components than those shown in FIG. 1.

However, in order to disclose illustrative embodiments, it is not necessary to show all of these components.

As shown in FIG. 1, the system 100 may comprise a robot arm 101, a fixture 102A mounted on the robot arm 101, a test plane 103, a fixed fixture102B mounted on the test plane 103, a docking station 104 and a control computer 105.

In some embodiments, the fixture may be of any form suitable for fixing a test device or a device under test. For example, the fixture may be a bracket, a screw or a socket. The test device and device under test may be, for example, electromagnetic coils, printed circuit boards (PCBs), magnetic probes, mobile phones or any wireless charging-related electronic products.

The robot arm 101 may comprise a distal portion that is configured to be releasably connected to a plurality of types of devices selected from a fixture, a probe and a solenoid test device. In some embodiments, the robot arm 101 is configured to grip a fixture 102A. For movement and rotation in the x, y, and z directions, the robot arm 101 may comprise a sliding and rotating motor. The robot arm 101 is configured to hold the fixture102A about the central axis of the fixture 102A and rotate for [−180, 180] degrees, and move the fixture 102A to different positions in the x, y, and z directions. The test plane 103 may be a horizontally placed plane having a surface that is parallel to the ground and parallel to the x-y plane. The fixture102B (i.e., a fixed fixture) may be mounted on the test plane 103 and may be used to fix the device under test during testing.

The positions of the test device and the device under test are interchangeable. In one embodiment, the test device may be fixed to a movable fixture 102A on the robot arm 101, and the device under test may be fixed to a fixed fixture 102B on the test plane 103. In another embodiment, the test device may be fixed to the fixed fixture 102B on the test plane 103, and the device under test may be fixed to the movable fixture 102A on the robot arm 101.

The docking station 104 may comprise a control computer 105. The robot arm 101 is rotatably mounted on the docking station 104. The test plane 103 may also be connected to the docking station 104. The control computer 105 may drive a motor on the robot arm 101 to move the movable fixture 102A to a target position. The control computer 105 may provide a user friendly interface and provide a number of predefined test procedures for a user to select. The control computer 105 may be connected to the robot arm 101 and the test plane 103, and control the robot arm 101 by driving a sliding and rotating motor. The control computer 105 may also provide a user friendly interface and software program to control a testing process and analyze test results. Additionally, the control computer 105 may read test data from an instrument or a fixture to automatically finish a post-processing process.

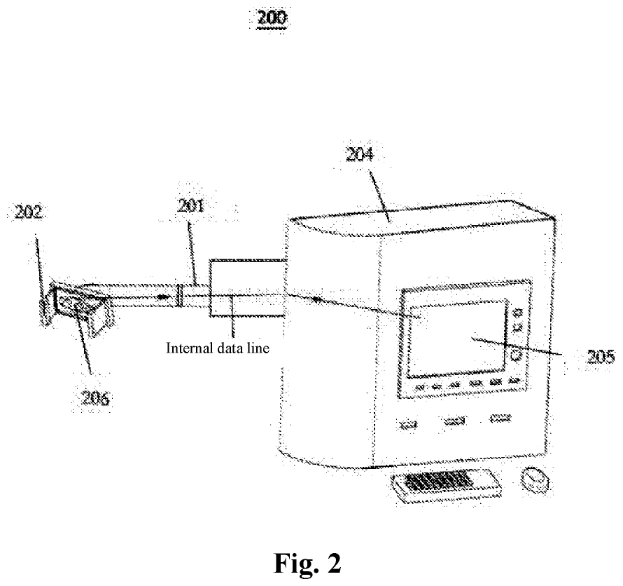

FIG. 2 is a schematic diagram of a fixture 202 mounted on an automatic test system 200 according to an exemplary embodiment of the present invention. In addition to controlling a test device and a device under test, the fixture 202 may also be configured to communicate with a control computer 205 via the internal data line built into a robot arm 201, and accordingly the fixture 202 may be designed to have a different interface 206.

In some embodiments, the interface 206 may comprise one or more electrical connectors that comprise a plurality of connecting lines for measuring voltage. The connecting lines may be connected to test pins of the test device, such as a RX PCB. The output voltage from the test device may be measured by the connection of the connection lines to the test pins. Measurement data may then be sent to the control computer 205 so that the control computer 205 may monitor and record the voltage values detected by the test device during testing.

In some embodiments, the interface 206 may comprise a data connector that may be connected to the test device for data exchange between the test device and the control computer 205. The control computer 205 may send control commands and receive feedback during testing. The interface 206 allows the test device to be electrically connected and in communication with the control computer 205. Thus, the automatic test system 200 may perform field testing on the wireless charging system.

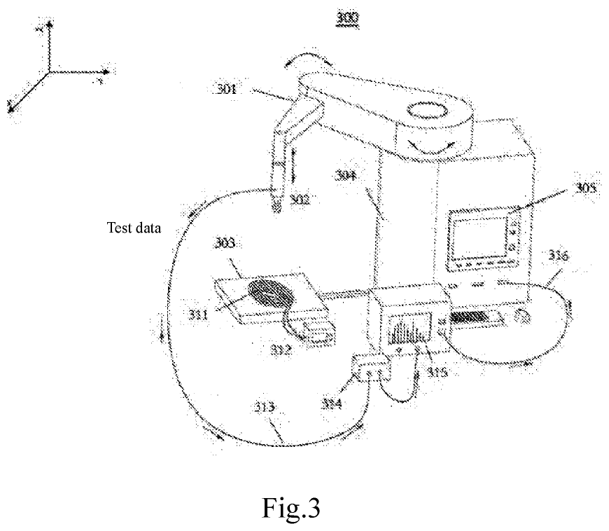

FIG. 3 illustrates an automatic test system 300 for measuring a magnetic field (magnetic field strength H) generated by a magnetic coil according to an exemplary embodiment of the present invention. The system 300 may comprise multiple components, some of which may be optional. In some embodiments, the system 300 may comprise more components than those shown in FIG. 3. However, in order to disclose illustrative embodiments, it is not necessary to show all of these components.

As shown in FIG. 3, the system 300 may comprise a robot arm 301, a magnetic field probe 302, a test plane 303, a docking station 304, a control computer 305 and an electromagnetic coil 311, a feed power supply 312, a cable 313, an amplifier 314, a test instrument 315 and a data cable 316.

In some embodiments, a fixed fixture may be placed on the test plane 303 to grip a DUT, such as the electromagnetic coil 311, a PCB prototype, or a wireless charging-related product. Devices under test may be interchanged according to different test requirements and scenarios. In some embodiments, the DUT is a magnetic coil. In some embodiments, the DUT is a TX coil.

In some embodiments, a movable fixture may be used to control the magnetic field probe 302 to measure a magnetic field generated by the electromagnetic coil 311. The magnetic field probe 302 may have different types. In one embodiment, the magnetic field probe 302 is a magnetic field strength probe that may detect the magnitude and frequency of the magnetic field. In another embodiment, the magnetic field probe 302 is a magnetic field phase probe that may detect phase information of the magnetic field. The frequency range of the magnetic field probe 302, the magnetic field sensitivity level, and the like may also be different. A specific magnetic field probe may be selected according to test scenarios and requirements. The magnetic field probe 302 is connected to the control computer 305, which controls and moves the magnetic field probe 302 to a different position.

The electromagnetic coil 311 may be configured to be connected to the feed power supply 312. The feed power supply 312 may be configured to provide electrical power, such as current, for the electromagnetic coil 311. The amplifier 314 is configured to connect to the magnetic field probe 302 and the test instrument 315 to amplify test data measured by the magnetic field probe 302. The cable 313 may be a 50 ohm coaxial cable and may be configured to connect the magnetic field probe 302, the amplifier 314 and the test instrument 315.

The test instrument 315 may vary depending on test requirements. In some embodiments, the test instrument 315 may be a spectrum analyzer. Such instrument may be configured to receive test data from the amplifier 314 and perform spectral analysis on the test data (measured magnetic field) to extract spectral information of the measured magnetic field. The test instrument 315 may also be configured to connect to the control computer 305 via the data cable 316. The data cable 316 may be a USB cable, a universal interface bus (GPIB) cable or an Ethernet cable. The control computer 305 may send control commands to the test instrument 315, which may transmit analyzed test data to the control computer 305.

In other embodiments, the system 300 may comprise a separate computer system that is not installed on the docking station 304, is connected to the test instrument 315 and is configured to receive and analyze test data.

The automatic test system 300 may also be used for different test needs and scenarios. In some embodiments, the system 300 may be configured to evaluate the uniformity of the magnetic field generated by the electromagnetic coil; in some embodiments, the system 300 may be used to identify the position of a primary radiation source of a prototype PCB or a wireless charging related product; and in other embodiments, the system 300 may also be used to estimate the strength and frequency of a magnetic field generated by a wireless charging-related product (e.g., a charging pad).

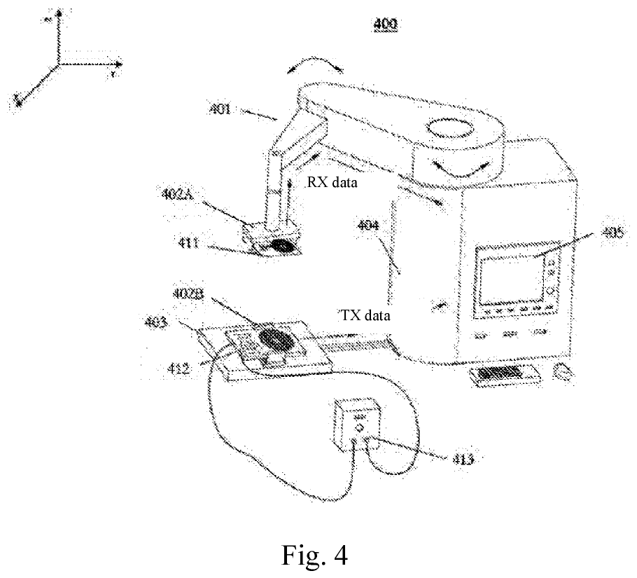

FIG. 4 illustrates an automatic test system 400 for measuring the efficiency and charging area of a wireless charging system according to an exemplary embodiment of the present invention. The system 400 may comprise multiple components, some of which may be optional. In some embodiments, the system 400 may comprise more components than those shown in FIG. 4. It is not necessary to show all of these components in order to disclose the illustrative embodiments.

As shown in FIG. 4, the system 400 may comprise a robot arm 401, a fixture 402A mounted on the robot arm 401, a test plane 403, a fixture 402B mounted on the test plane 403, a docking station 404, a control computer 405, an RX board 411 with an RX coil, a TX board 412 with a TX coil and a power supply 413.

The fixture 402A is a movable fixture mounted on the robot arm 401 and configured to grip and move the RX board 411 or a wireless power receiver-related product. The fixture 402B is a fixed fixture placed on the test plane 403 and is configured to grip the TX board 412 or a wireless charging pad.

The power supply 413 is configured to supply power, such as current, to the TX board 412 which is configured to input the power to the TX coil. The TX coil may be magnetically coupled to the RX coil, and the RX coil is wirelessly charged by the TX coil. The power transmitted during wireless charging may be transmitted to the RX board 411 which may further output such power to a load.

The RX board 411 and the TX board 412 may comprise a plurality of test pins that may be connected to connectors (e.g., connecting lines) on the fixtures 402A and 402B. The connector allows a device for testing to be electrically connected to and to communicate with the control computer or other test instrument. With the connection between the test pin and a connection line, the input voltage and current of the TX board 412 and the output voltage and current of the RX board 411 may be detected and transmitted to the control computer 405. Other parameters, such as the voltage of a rectifier on the RX board 411, may also be measured and transmitted to the control computer 405. The control computer 405 may also determine the relative position between the TX and RX coils by moving the RX board 411 to any position within a certain range by means of the robot arm 401. Thus, the control computer 405 is able to obtain parameters for calculating wireless charging efficiency at any relative position. The wireless charging efficiency of any relative position may be defined as:

$$η = \frac{{V}_{out} {I}_{out}}{{V}_{in} {I}_{in}}$$

Here, Vₒᵤₜ, Iₒᵤₜ, Vᵢₙ and Iᵢₙ represent the output voltage, the output current and input voltage of the RX coil, and the input current of the TX coil, respectively.

The automatic test system 400 may also be used for different test needs and scenarios. In some embodiments, the system 400 may be configured to measure charging efficiency when the TX coil and RX coil are at different relative positions and offsets; in some embodiments, the system 400 may be used to characterize a charging region; and in some other embodiments, the system 400 may also be used to monitor changes in parameters (e.g., rectifier voltage) during a wireless charging process.

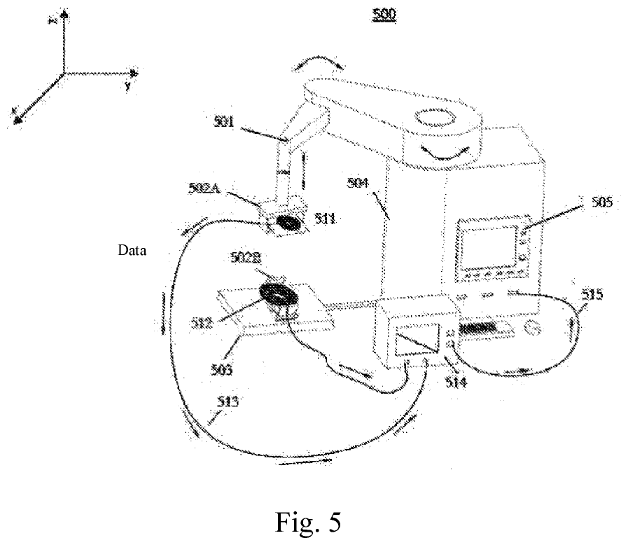

FIG. 5 illustrates an automatic test system 500 for measuring a coupling coefficient according to an exemplary embodiment of the present invention. The system 500 may comprise multiple components, some of which may be optional. In some embodiments, the system 500 may comprise more components than those shown in FIG. 5. However, it is not necessary to show all of these components to disclose illustrative embodiments

As shown in FIG. 5, the system 500 may comprise a robot arm 501, a fixture 502A fixed to the robot arm 501, a test plane 503, a fixture 502B fixed to the test plane 503, a docking station 504, a control computer 505, an RX coil 511, one or more TX coils 512, a cable 513, a test instrument 514 and a data cable 515.

The fixture 502A mounted on the robot arm 501 is a movable fixture and is configured to grip and move the RX coil 511. The fixture 502B placed on the test plane 503 is a fixed fixture and is configured to grip the TX coil 512. The TX coil 512 may comprise one or more TX coils placed at different positions. In some embodiments, an additional magnetic material such as a ferrite sheet may be fixed to the TX and RX coils.

The cable 513 may be a 50 ohm coaxial cable and may be configured to connect the RX coil 511, the TX coil 512 and the test instrument 514.

The test instrument 514 may vary depending on test requirements. In some embodiments, the test instrument 514 may be a vector network analyzer (VNA). The VNA 514 may comprise two ports: Port 1 and Port 2, which are connected to the TX, RX coils via the cable 513, respectively. The VNA 514 may also be configured to connect to the control computer 505 via the data cable 515. The data cable 515 may be a USB cable, a universal interface bus (GPIB) cable or an Ethernet cable. The control computer 505 may send control commands to the VNA 514 which may transmit test results to the control computer 505.

The VNA is a test system that may be used to characterize the radio frequency (RF) performance of RF and microwave devices according to network scatter parameters (S parameters). The S parameters describe the electrical behaviors of a linear grid when various steady state stimuli are performed by means of electrical signals. The S parameters may be used to represent many of the electrical properties of a component network (e.g., an inductor, a capacitor, a resistor). The S parameters of the wireless charging system may be measured using the VNA 514 and sent to the control computer 505. A coupling coefficient between the TX and RX coils may then be extracted from the S parameters. In addition, the measured S parameters may help build a coil model for further simulation work.

The automatic test system 500 may also be used for different test needs and scenarios. In some embodiments, the system 500 may be used to measure the coupling coefficients between the TX and RX coils at different distances and offsets; in some other embodiments, the system 500 may also be used to acquire parameters, such as self-inductance and mutual inductance, of a wireless charging system, so as to build a simulation model.

It should be noted that one or more of the functions described above may be implemented by software or firmware that is stored in a memory and executed by a processor or is stored in a program memory and executed by a processor. The software or firmware may also be stored and/or transmitted in any non-transitory computer readable medium for use by or in connection with an instruction execution system, apparatus or device, such as a computer-based system and a processor-containing system, or other systems that may acquire instructions from an instruction execution system, apparatus or device and execute such instructions. Within the context of the present disclosure, a “computer-readable medium” may be any medium that contains or stores a program for use by or in connection with an instruction execution system, apparatus or device. The computer readable medium may comprise, but is not limited to, an electronic, magnetic, optical, electromagnetic, infrared, or semiconductor system, apparatus or device, a portable computer disk (magnetic), a random access memory (RAM) (magnetic), a read only memory (ROM) (magnetic), an erasable programmable read only memory (EPROM) (magnetic), a portable optical disc such as a CD, CD-R, CD-RW, DVD, DVD-R or DVD-RW or flash memory, such as compact flash cards, secure digital cards, USB storage devices and memory sticks.

The scope of the present invention is not limited to the specific preferred embodiments described herein, as these embodiments are intended to illustrate several aspects of the present invention. In fact, various modifications of the present invention in addition to those shown and described herein will become apparent to those skilled in the art. Thus, such modifications are intended to fall within the scope of the following appended claims.

1. An automatic test system for testing a wireless charging system, comprising:
a robot arm, configured to grip a first fixture;
a test plane, configured to grip a second fixture;
a docking station, connected to the robot arm; and
a control computer, configured to control the robot arm and receive test data, the second fixture being configured to grip a device under test of the wireless charging system, and the first fixture being configured to grip a test device for testing the device under test and generate test data.

2. The system according to claim 1, wherein the robot arm is configured to move the first fixture in x, y and z directions and to enable the first fixture to rotate for [−180,180] degrees around the central axis of the first fixture.

3. The system according to claim 1, wherein the test plane is a horizontally placed plane having one surface parallel to an x-y plane.

4. The system according to claim 1, wherein the test device comprises at least one of a magnetic coil, a printed circuit board, a magnetic probe and an electronic power receiver-related product.

5. The system according to claim 1, wherein the device under test comprises at least one of an electromagnetic coil, a PCB and an electronic power transmitter-related product.

6. The system according to claim 1, wherein the control computer further comprises a non-transitory computer readable medium storing program codes for controlling a testing process, and measuring and analyzing test data.

7. The system according to claim 1, further comprising an internal data line in the robot arm, wherein the first fixture is configured to communicate with the control computer via the internal data line.

8. The system according to claim 1, wherein the first fixture comprises a plurality of connecting lines configured to be connected to the test device.

9. The system according to claim 1, wherein the first fixture comprises a data connector for exchanging data between the test device and the control computer.

10. The system according to claim 1, further comprising:
a feed power supply, configured to supply current to the device under test;
a probe, gripped by the first fixture;
a test instrument, configured to receive and analyze test data and to communicate with the control computer via a data line; and
an amplifier, connected to the probe and the test instrument, and configured to amplify the test data.

11. The system according to claim 10, wherein the probe is a magnetic field strength probe configured to detect the magnitude and frequency of a magnetic field generated by the device under test.

12. The system according to claim 10, wherein the probe is a magnetic field phase probe configured to detect phase information of a magnetic field generated by the device under test.

13. The system according to claim 10, wherein the test instrument is a spectrum analyzer configured to perform spectral analysis on the test data to extract spectral information of a magnetic field generated by the device under test.

14. The system according to claim 1, further comprising:
an RX board, gripped by the first fixture and coupled to an RX coil of the wireless charging system;
a TX board, gripped by the second fixture and coupled to a TX coil of the wireless charging system; and
a power supply, configured to supply current to the TX board.

15. The system according to claim 14, wherein the first fixture is configured to measure an output voltage Vₒᵤₜ and an output current Iₒᵤₜ of the RX coil and to transmit a measured signal to the control computer.

16. The system according to claim 15, wherein the charging efficiency of the wireless charging system is calculated by using the following formula when the TX coil and the RX coil are in a relative position:
$$η = \frac{{V}_{out} {I}_{out}}{{V}_{in} {I}_{in}}$$
where Vᵢₙ and Iᵢₙ represent the input voltage and input current of the TX coil respectively, and the relative position is controlled by the control computer.

17. The system according to claim 1, further comprising:
an RX coil of the wireless charging system, the coil being gripped and assembled by the first fixture;
a TX coil of the wireless charging system, the coil being gripped and assembled by the second fixture; and
a vector network analyzer, configured to acquire S parameters of the wireless charging system, wherein the vector network analyzer comprises two ports respectively connected to the TX coil and the RX coil, the vector network analyzer is configured to transmit the S parameters to the control computer, and the control computer is configured to extract a coupling coefficient from the S parameters.

18. The system according to claim 17, further comprising a ferrite sheet attached to the TX and RX coils.

19. An automatic test system for testing a wireless charging system, comprising:
a robot arm, comprising a distal portion that is configured to be releasably connected to a plurality of types of devices selected from a fixture, a probe and a test device;
a test plane, configured to control a device for testing of the wireless charging system;
a docking station, connected to the robot arm; and
a control computer, configured to control the robot arm and receive test data.

20. An automatic test system for testing a wireless charging system, comprising:
a robot arm, configured to grip a first fixture;
a test plane, configured to grip a second fixture;
a docking station, connected to the robot arm; and
a control computer, configured to control the robot arm and receive test data, wherein,
the first and second fixtures each comprise a connector that is configured to electrically connect to a device for testing; and the robot arm comprises an internal data line configured to be connected to a device assembled by the first fixture to allow the device to communicate with the control computer.
